(19) United States
(12) Patent Application Publication
(10) Pub. No.: US 2024/0186149 A1
(43) Pub. Date: Jun. 6, 2024

(54) Methods for Etching Molybdenum

(71) Applicant: Tokyo Electron Limited, Tokyo (JP)

(72) Inventors: Yun Han, Albany, NY (US); Peter Lowell George Ventzek, Austin, TX (US); Roberto Longo Pazos, Austin, TX (US); Alok Ranjan, Austin, TX (US)

(21) Appl. No.: 18/062,449

(22) Filed: Dec. 6, 2022

Related U.S. Application Data
(60) Provisional application No. 63/287,371, filed on Dec. 8, 2021.

(51) Int. Cl. H01L 21/3213

(52) U.S. Cl. CPC H01L 21/32139; H01L 21/32136

(57) ABSTRACT

A substrate processing method including: providing a substrate containing an etch mask over a metallic molybdenum layer in a recessed feature; exposing the substrate to a plasma-excited deposition gas that forms an etch protection layer on a sidewall of the recessed feature; and exposing the substrate to a plasma-excited etching gas that etches the metallic molybdenum layer according to the etch mask, where the exposing steps are alternatingly performed a plurality of times.

### CROSS-REFERENCE TO RELATED APPLICATIONS

This application claims the benefit of U.S. Provisional Application No. 63/287,371, filed on Dec. 8, 2021, which application is hereby incorporated herein by reference.

### TECHNICAL FIELD

The present invention relates generally to methods for fabricating a semiconductor device, and, in particular embodiments, to methods for dry etching molybdenum.

### BACKGROUND

A semiconductor integrated circuit (IC) is a network of electronic components built by sequentially depositing and patterning layers of various materials to form a monolithic structure over a substrate. At each new technology node, the component density is roughly doubled to lower the unit cost of ICs. Enabled by advances in patterning, several hundred transistors may be packed in a 1 μm² area and connected to signals and power supplies by metal lines having a half-pitch less than 15 nm. Resistances of such narrow lines depend mainly on conduction near the edges. Liners, used as metal diffusion barriers, and random electron scattering along the metal edges give rise to a narrow width effect (NWE), where resistance rises sharply with reducing width. Hence, for sub-5 nm nodes, metallic molybdenum, having low-diffusivity in silicon oxide (eliminates a need for diffusion barriers), low bulk mean free path (less edge scattering), high melting point, and low thermal expansion coefficient, is a metal of interest for wires in the highest density interconnect levels. While it has promising properties, integrating molybdenum into high volume IC manufacturing requires dry etching methods with good control over etch profile, etch rate, and etch selectivity to masking materials and underlying layers. Hence, further innovation in processes for dry etching of metallic molybdenum is desired.

### SUMMARY

A substrate processing method including: providing a substrate containing an etch mask over a metallic molybdenum layer in a recessed feature; exposing the substrate to a plasma-excited deposition gas that forms an etch protection layer on a sidewall of the recessed feature; and exposing the substrate to a plasma-excited etching gas that etches the metallic molybdenum layer according to the etch mask, where the exposing steps are alternatingly performed a plurality of times.

A substrate processing method including: providing a substrate containing an etch mask over a metallic molybdenum layer in a recessed feature; depositing an etch protection layer in the recessed feature, where the etch protection layer includes an oxide layer; performing a breakthrough etching step that etches through the etch protection layer at a bottom of the recessed feature; and exposing the substrate to a plasma-excited etching gas that etches the metallic molybdenum layer according to the etch mask.

A substrate processing method including: providing a substrate containing an etch mask over a metallic molybdenum layer in a recessed feature; depositing an etch protection layer on a sidewall of the etch mask, where the etch protection layer includes an oxide layer; and exposing the substrate to a plasma-excited etching gas that etches the metallic molybdenum layer according to the etch mask, where the depositing and the exposing are alternatingly performed a plurality of times.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates a flowchart summarizing a process flow for patterning an molybdenum layer, in accordance with an embodiment;

FIGS. 1B-1D illustrate cross-sectional views of a semiconductor device at various intermediate steps of the process flow summarized in the flowchart illustrated in FIG. 1A;

FIGS. 2A and 2B illustrate cross-sectional views of a semiconductor device showing undesirable etch characteristics and defects resulting from patterning a metallic molybdenum layer using an anisotropic dry etch process having an insufficient process window;

FIG. 3A illustrates a flowchart summarizing a gas pulsing cyclic etch technique for patterning a metallic molybdenum layer, in accordance with an embodiment;

FIGS. 3B-3F illustrate various cross-sectional views of a semiconductor device at various intermediate stages of patterning a metallic molybdenum layer using the gas pulsing cyclic etch technique summarized in the flowchart illustrated in FIG. 3A;

FIG. 4 illustrates a flowchart summarizing an ALD-based cyclic etch technique for patterning a metallic molybdenum layer, in accordance with an embodiment; and

FIG. 5 illustrates a flowchart of a single cycle of a cyclic etch technique, in accordance with an embodiment.

### DETAILED DESCRIPTION OF ILLUSTRATIVE EMBODIMENTS

Embodiments of dry etching methods for subtractive etching of metallic molybdenum are described in this disclosure. In this disclosure, metallic molybdenum refers to elemental molybdenum and its alloys, including molybdenum with a small amount of impurities and dopants. In subtractive etching of metal, a patterned etch mask is formed over a metal layer, and the pattern is transferred to the metal layer by directly etching recessed features that extend through the metal to form a pattern of metal lines. Typically, a dry etch process, such as reactive ion etching (RIE) is used. Prior to forming the etch mask, the metal layer is formed uniformly over a planarized surface of an interlayer dielectric (ILD) layer. After patterning the metal by subtractive etching, another ILD layer may be formed filling the recessed features and covering the metal lines for insulation. Conventional copper interconnect uses the more complex damascene process flow, where trenches for metal lines are etched into an ILD layer using a patterned etch mask and overfilled with metal. The overfill material, including all metal deposited over the dielectric surface between trenches, is removed using, for example, a chemical mechanical planarization (CMP) to form metal lines inlaid in the ILD. As known to persons skilled in the art, depositing metal over a planar surface is simpler than filling 10 nm to 20 nm wide trenches with void-free metal. Furthermore, the CMP step is expensive, hence increases the fabrication cost.

Patterning metal by subtractive etching, being simpler and less expensive, is preferred over damascene etching provided the etch process meets appropriate manufacturing criteria. For example, the etch process must meet specifications for etch rate, etch selectivity, sidewall profile, line-edge roughness (LER), and defect density (e.g., of bridging and line break defects) with good control to achieve robust manufacturing. Dry etch processes for patterning a metal layer comprising molybdenum are described in this disclosure that provide several advantages, for example, suppressed lateral etching to reduce undercut, low LER, and a more vertical edge profile, in addition to improved control of etch rate and etch selectivity.

The ILD layer is typically a silicon oxide-based dielectric. Copper being a contaminant that diffuses easily in silicon oxide, a continuous diffusion barrier lining the trenches is needed before filling the trenches with copper. Generally, a sufficiently thick (e.g., 1.5 nm to 3 nm) liner is formed to ensure that there are no holes or breaks at edges and corners through which the copper may leak out into the ILD and degrade a time-dependent dielectric breakdown (TDDB) lifetime of the interconnect structures. The liner may increase resistance of the metal line mainly in two ways. A low-resistivity core metal may be displaced by a liner material comprising a higher resistivity metal or insulator. Additionally, a higher diffusive electron scattering rate at interfaces of the core metal and the liner may further increase the line resistance. Diffusive scattering along the edges is more dominant in a metal where the bulk mean free path of electrons (λ) is longer than a cross-sectional dimension of the line. The geometric effect (reduced cross-sectional area) and the scattering effect (higher scattering rate at the interface), being edge effects, cause the metal line resistance with decreasing W to rise more rapidly than 1/W. Here, W refers to a linewidth that includes the liner. For example, in a damascene process, W would be the trench width. This implies that the effective resistivity, ρ(W), increases with decreasing W, an undesirable phenomenon referred to as the narrow width effect (NWE) in this disclosure. Effective resistivity, ρ(W), is the line resistance normalized to L/(Wt), where L is a length of the line and t is a thickness of the metal. Undesirable consequences of an increased ρ(W) due to NWE include a bigger ohmic drop (reducing circuit speed) and more Joule heating leading to accelerated electromigration (EM) at the higher temperature. Copper, requiring a diffusion barrier liner, exhibits a strong NWE. For example, ρ(W) may rise an order of magnitude above its bulk resistivity (ρₒ=16.8 Ω-nm) as W is reduced to 10 nm.

The strong NWE of copper lines is a concern in scaling copper interconnect, a concern that has stimulated research on replacing copper with a suitable metal, at least at the lower metal levels, where the most densely packed metal lines are placed. As mentioned in the background section, because of its low diffusivity in silicon oxide, molybdenum does not require a diffusion barrier. Furthermore, due to its short λ=11.2 nm, the diffusive scattering along edges of molybdenum lines is not as dominant as that along edges of copper lines, where λ=39.9 nm. The geometric effect (reduced cross-sectional area) becomes significant as W falls below, roughly, ten times the liner thickness, and the scattering effect (higher scattering rate at the interface) has severe impact on ρ(W) as W is reduced below 2. Indeed, when comparing different metals, ρₒλ is often used as an indicator of the magnitude of the scattering effect component of NWE. The metric, ρₒ×λ, is 670 Ω-nm² for copper. In comparison, ρₒ×λ, is 600 Ω-nm² for molybdenum, despite having a higher ρₒ=53.4 Ω-nm. Thus, NWE is less severe in molybdenum relative to copper. For this and other attractive characteristics, such as a reasonably low ρₒ, low coefficient of thermal expansion (5×10⁻⁶ per ° C.), high melting point (an indicator for good EM reliability), and stable interface with silicon oxide, metallic molybdenum is being considered for replacing copper.

Replacing damascened copper with barrier-free metal lines patterned using subtractive etching for the tightest pitch wiring levels in IC designs is one of several architectural changes that may be imminently needed to meet the performance, power, area, and cost (PPAC) goals of technology scaling. As explained above, metallic molybdenum holds promise for this purpose. Integrating molybdenum interconnect into an IC fabrication flow requires processes for forming, over a substrate, a metal layer comprising metallic molybdenum, forming a patterned etch mask over the metal layer, and transferring the pattern to the metal layer by etching a pattern of recessed features extending through the metal layer. In this disclosure, we describe embodiments of methods for etching the pattern of recessed features extending through a metallic molybdenum layer and exposing a portion of a major surface of an underlying layer. The methods employ cyclic processing to separate out controlling the vertically advancing etch-front from controlling the sidewall profile to achieve improved process optimization. For example, each cycle of the cyclic process may comprise a first part using a set of process parameters and gases optimized for depositing passivating solid byproducts for sidewall protection, and a second part using a different set of process parameters and gases optimized for selectively removing metallic molybdenum to extend the recessed features vertically. The temporal separation of the deposition and etching steps of the cyclic etching process allows for improved optimization that provides a wider process window to achieve a smooth vertical sidewall with negligible undercut and footing defects during manufacturing.

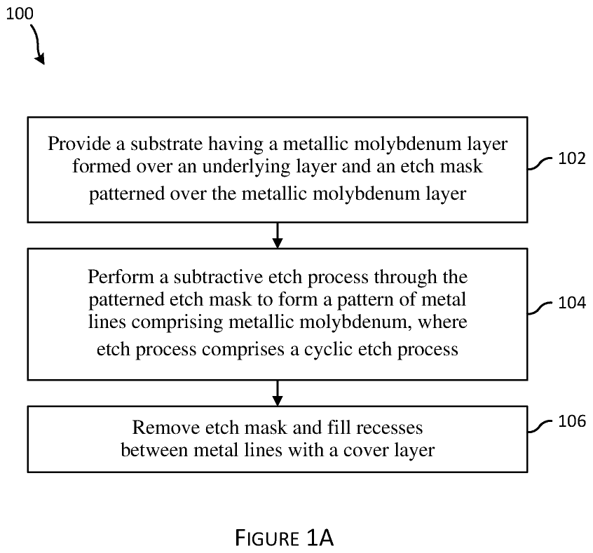

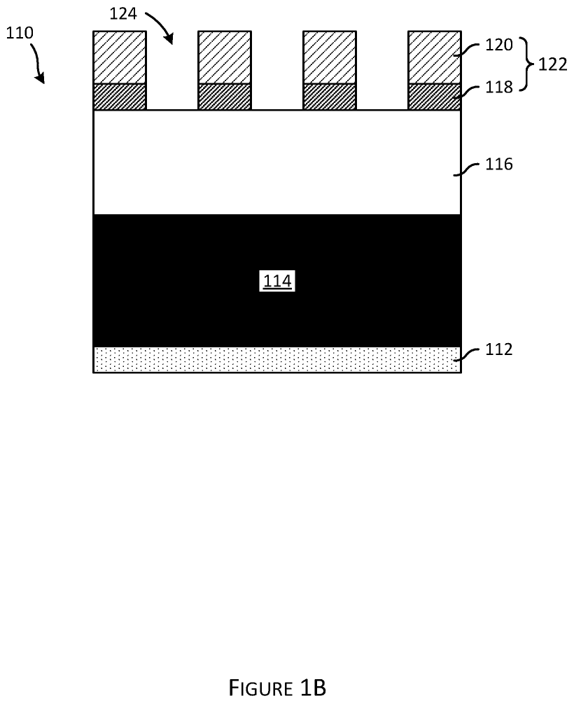

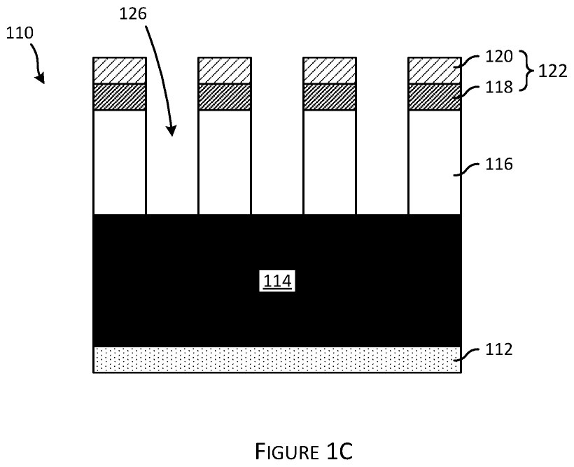

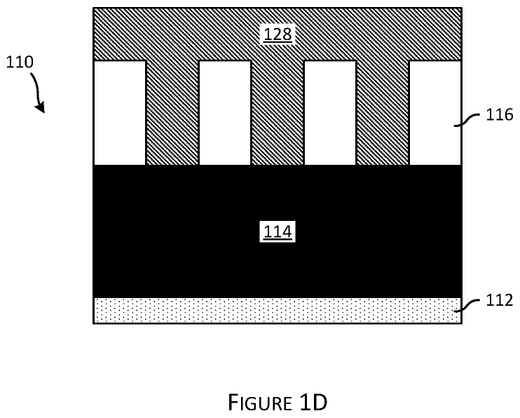

FIG. 1A illustrates a flowchart summarizing a process flow 100 for patterning a metallic molybdenum layer using subtractive etching. The process flow 100 may be a portion of a fabrication flow of a semiconductor device 110, in which the layer of metal lines comprising metallic molybdenum has been integrated using the embodiments described in this disclosure. The basic process steps in process flow 100 are described with reference to cross-sectional views of the semiconductor device 110, illustrated schematically in FIGS. 1B-1D.

As indicated in box 102 in the flowchart in FIG. 1A, the process flow 100 comprises providing a substrate having a metallic molybdenum layer formed over an underlying layer and an etch mask patterned over the metallic molybdenum layer. In box 104, a subtractive etch process is performed through the patterned etch mask to form a pattern of metal lines comprising metallic molybdenum. The subtractive etch process comprises a cyclic etch process. Each cycle of the cyclic etch process comprises depositing an etch protection layer in a recessed feature in the metallic molybdenum layer and anisotropically etching metallic molybdenum. After the metal lines are formed, any remaining portion of the etch mask may be removed, as indicated in box 106.

FIG. 1B illustrates a cross-sectional view of the semiconductor device 110 after a metallic molybdenum layer 116 has been formed over an underlying layer 114 and an etch mask 122 patterned over the metallic molybdenum layer 116, as indicated in box 104 in the flowchart in FIG. 1A. The underlying layer 114 may comprise a dielectric layer, for example, an ILD layer comprising a low-k silicon oxide or an insulating etch-stop layer in the ILD layer. The metallic molybdenum layer 116 may be formed using a suitable film growth technique such as plasma enhanced chemical vapor deposition (PECVD). A thin adhesion layer (not shown) (e.g., TiN or TaN) may optionally be deposited on the underlying layer 114 before forming the metallic molybdenum layer 116. In addition to helping adhesion, the adhesion layer may help improve the morphology of the metallic molybdenum layer 116 during film growth. Various other layers below the underlying layer 114 are collectively shown as a substrate layer 112.

The etch mask 122 is a first pattern of recessed features, where each recessed feature 124 has vertical sidewalls and a bottom exposing a portion of a major surface of the metallic molybdenum layer 116. In the example embodiment in FIG. 1B, the etch mask 122 comprises a patterned hardmask layer 118 and a patterned photoresist layer 120. The patterned hardmask layer 118 may be formed by depositing hardmask material over the metallic molybdenum layer 116 and, subsequently, etching the hardmask material using the patterned photoresist layer 120 as an etch mask. The patterned photoresist layer 120 may be formed using a suitable lithography technique such as extreme ultraviolet (EUV) lithography. A minimum half-pitch (critical dimension) in the patterned photoresist layer may be from about 5 nm to about 15 nm. Examples of hardmask material include silicon oxide, silicon nitride, titanium nitride, and the like, or a combination of multiple layers. In some other embodiments, the patterned hardmask layer 118 may be omitted from the etch mask 122.

In FIG. 1C, a subtractive etch process is performed through the patterned etch mask 122 to anisotropically remove metallic molybdenum layer 116 to further extend the recessed features 124 in FIG. 1B to form a second pattern of recessed features, where each recessed feature 126 has vertical sidewalls and a bottom exposing a portion of a major surface of the underlying layer 114. Depending on the selectivity of the etch chemistry, a certain portion of the etch mask 122 is eroded, as illustrated in FIG. 1C. As mentioned above, the embodiments of etch processes described in this disclosure employ cyclic processing to achieve the vertical sidewalls illustrated schematically in FIG. 1C. In each cycle of the cyclic etch process, the processing switches between a sidewall passivation step and an etching step that vertically removes metallic molybdenum. Several different embodiments of this method for etching metallic molybdenum are described in detail further below. The metal thickness being between about 50 nm to about 200 nm and the minimum half-pitch in the pattern being about 5 nm to about 15 nm, the aspect ratio of the recessed feature 126 is in a range where good control over sidewall profile has to be provided for the process to be manufacturable.

As illustrated in FIG. 1D, after completing the subtractive etch process, any residual portion of the etch mask 122 may be removed. Generally, a cover layer 128, for example, another ILD layer is formed over the patterned metallic molybdenum layer 116 covering the metal lines and filling the spaces between lines.

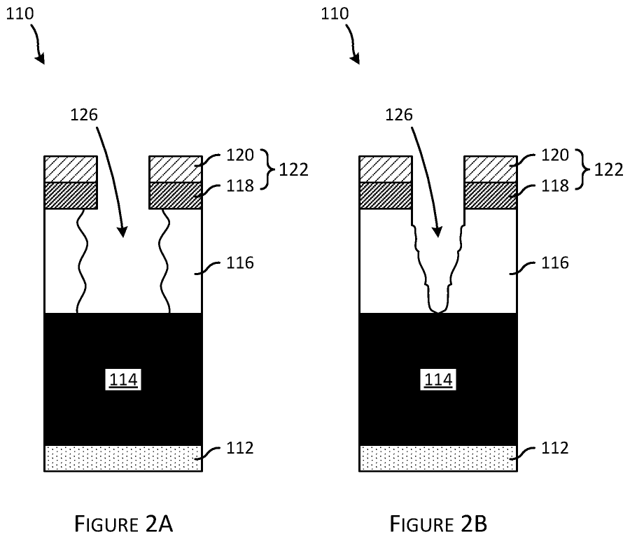

FIGS. 2A and 2B show undesirable etch characteristics and defects resulting from an insufficient process window for an anisotropic dry etch process (e.g., a conventional RIE process) used to etch recessed features 126 in the metallic molybdenum layer 116 during the etch step described with reference to FIG. 1C.

Generally, the substrate is exposed to plasma in a processing chamber, where a halogen (e.g., chlorine or fluorine) based chemistry is utilized to etch molybdenum. Halogen radicals excited by plasma react with molybdenum to form volatile byproducts that may be pumped out of the chamber. In the conventional RIE process, anisotropy is achieved by applying a bias signal (e.g., a DC bias or a radio-frequency (RF) bias) to the substrate, and by using a plasma-excited gaseous mixture containing, in addition to halogens, elements such as carbon, hydrogen, and oxygen to cause chemical reactions that form solid byproducts (e.g., oxides and polymers). The solid byproducts are deposited selectively on vertical surfaces to protect the sidewalls of the recessed feature, a technique referred to as sidewall passivation. The passivation layer is formed selectively on the sidewalls by sputtering away solid byproducts from the floor of the recessed feature with high energy ions (e.g., argon ions) excited by plasma and directed vertically by the bias signal. In addition, bombarding a surface with ions enhances the reaction rate there by breaking the bonds between molybdenum atoms, hence facilitating bonding with halogen radicals. Thus, the vertical etch rate is enhanced by ion bombardment at the bottom surface, while the lateral etch rate is retarded by sidewall passivation.

A delicate balance has to be struck between the passivation rate and the removal rate to provide a wide enough process window for robust manufacturing. With aggressive scaling of lateral dimensions, the top opening of the recessed feature 126 gets smaller and the aspect ratio of the recessed feature 126 gets higher. Thus, it becomes increasingly difficult to open up a sufficiently wide process window with conventional RIE methods. FIG. 2A illustrates an example of an undercut or lateral etch formed in the metallic molybdenum layer when a lean halogen chemistry is used. A lean halogen chemistry refers to a gaseous mixture, where the relative halogen content is increased, so that there is more removal and less passivation. As illustrated schematically in FIG. 2A, insufficient sidewall passivation has resulted in excessive lateral etching. A combination of lateral etching and narrow linewidth may even cause line-break defects. FIG. 2B illustrates a different example, where a tapered sidewall profile and bottom footing defects are formed when the etch chemistry is adjusted to promote sidewall passivation by depositing a protective layer of solid byproducts on the sidewalls. In the example illustrated in FIG. 2B, the footing is severe enough to cause a bridging defect.

It is further noted that poor sidewall profile control increases a roughness of a surface along the sidewalls. This exacerbates the LER of the metal lines in the etched pattern beyond an LER of the lines in the patterned etch mask 122 introduced by the lithography process. Since line resistance depends on linewidth (W), increased LER increases the variance and average values of resistance of short metal lines, even for a fixed resistivity, ρ. With NWE, i.e., ρ=ρ(W), the effect of LER on line resistance is exacerbated. Additionally, the high frequency components of LER (i.e., roughness over a wire length of about 1 nm or less) increases diffusive edge scattering by reflecting electrons at random angles, independent of the incident angle, as opposed to specular edge scattering, where the angle of reflection is equal to the angle of incidence. Specular scattering conserves electron momentum in the direction of current flow, whereas diffusive scattering randomizes momentum, which increases ρ(W), thereby undesirably increasing the NWE. Embodiments of the invention, described below, provide greater flexibility in adjusting sidewall passivation and material removal, hence improved sidewall profiles and sidewall profile control.

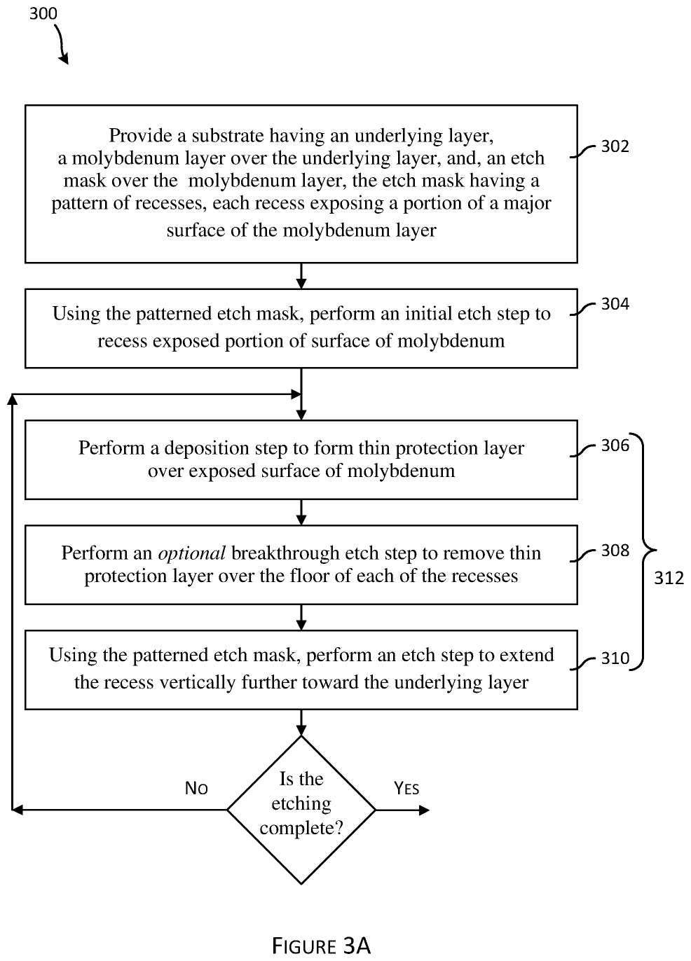

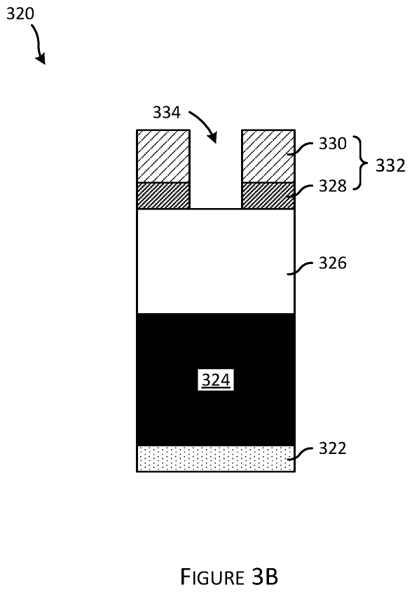

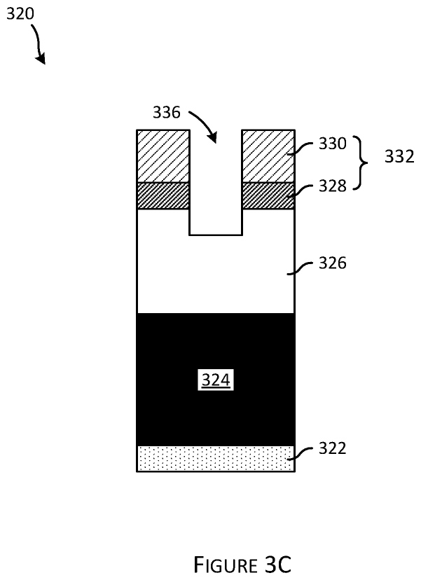

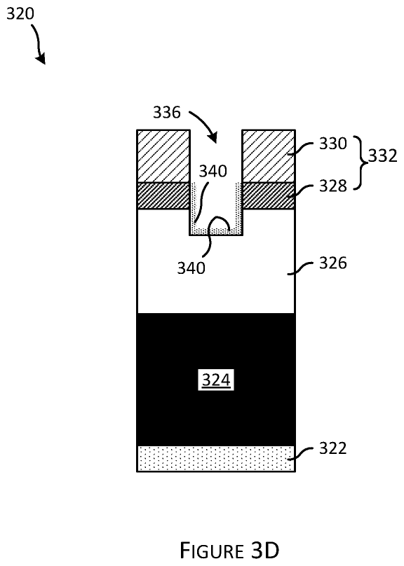

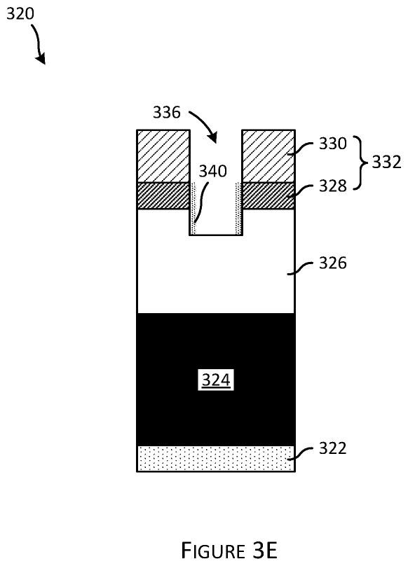

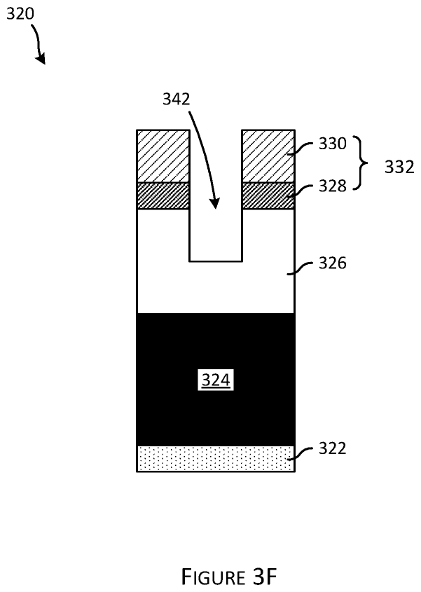

An embodiment implementing the process flow 100 using a gas pulsing cyclic etch technique 300 is described with reference to FIGS. 3A-3F. FIG. 3A illustrates a flowchart summarizing the gas pulsing cyclic etch technique 300 and FIGS. 3B-3F illustrate various cross-sectional views of a semiconductor device 320 at various intermediate stages of patterning a metallic molybdenum layer using the gas pulsing cyclic etch technique 300.

As indicated in box 302 of the flowchart illustrated in FIG. 3A and shown in the cross-sectional view of a semiconductor device 320 in FIG. 3B, the gas pulsing cyclic etch technique 300 receives an incoming substrate, which is similar to the substrate described above with reference to FIG. 1B. The substrate comprises an underlying layer 324 and, formed over the underlying layer 324, is a metallic molybdenum layer 326. A patterned etch mask 322 is formed over the metallic molybdenum layer 326. The pattern comprises recessed features 334 having an exposed surface of the metallic molybdenum layer 326 as the floor of each recessed feature. In one embodiment, the patterned etch mask 322 comprises a patterned photoresist layer 330 and a hardmask layer 328, for example, a tetraethyl orthosilicate (TEOS) hardmask layer 328. The hardmask layer 328 has been patterned using the photoresist layer 330 as a masking layer. In some other embodiments, the patterned photoresist layer 330 may not be present on the incoming substrate, having been removed during the process of patterning the hardmask layer 328.

In some embodiments, the gas pulsing cyclic etch technique 300 includes an initial etching step (box 304 in FIG. 3A) that anisotropically etches a portion of the metallic molybdenum layer 326 to extend the recessed feature 334, forming an extended recessed feature 336, as seen in the cross-sectional view of the semiconductor device 320 illustrated in FIG. 3C. After the initial etch step (box 304) completes forming the extended recess feature 336, gas pulsing cycles in the gas pulsing cyclic etch technique 300 may be performed.

As illustrated in the flowchart in FIG. 3A, each gas pulsing cycle 312 comprises two parts: a first part is a deposition step (box 306 and FIG. 3D), and a second part is an etch step (box 310 and FIG. 3F). In some embodiment, the gas pulsing cyclic etch technique 300 may have an optional breakthrough etch step (box 308 and FIG. 3E) inserted between the deposition step in box 306 and the etch step in box 310 to expose the molybdenum surface vertically below the material deposited over the floor of the extended recessed feature 336.

During the deposition step (FIG. 3A-box 306 and FIG. 3D) of the gas pulsing cyclic etch technique 300, the substrate is exposed to a plasma-excited deposition gas. As illustrated in the cross-sectional view of the semiconductor device 320 in FIG. 3D, exposure to the plasma-excited deposition gas forms an etch protection layer 340 along the sidewall and floor of the recessed feature 336. The set of plasma process parameters and gases used for the deposition step in box 306 of the gas pulsing cyclic etch technique 300 may be optimized for depositing passivating solid byproducts for sidewall protection.

In some embodiments, the deposition gas includes a fluorocarbon (CₓF_{y}), or a hydrofluorocarbon (CₓH_{y}F_{z}) having a ratio of carbon to fluorine atoms greater than 1/4 and less than or equal to 1. Non-limiting examples of fluorocarbons that may be a deposition gas include C₂F₄, C₂F₆, C₄F₈, and C₄F₆. Non-limiting examples of hydrofluorocarbons that may be a deposition gas include CHF₃, CH₂F₂, and CH₃F. Additional gases that may be included in the deposition gas are H₂, O₂, and a diluent inert gas (e.g., argon, helium, or nitrogen). The plasma process parameters include a chamber pressure of about 30 mTorr to about 300 mTorr, an RF source power of about 50 W to about 800 W at a frequency of about 25 MHz to about 60 MHZ, and a pulsed RF bias power of about 0 W (no RF bias) to about 100 W at a frequency of about 0.1 kHz to about 100 kHz. The substrate temperature is controlled from about 0° C. to about 60° C. In these embodiments, the formed etch protection layer 340 (shown in FIG. 3D) are organic films comprising C and H atoms, for example, an organic film which results from the deposition of chemical species produced from CH₃F plasma dissociation.

In some other embodiment, the deposition gas comprises a sulfur-containing gas, for example, sulfur dioxide (SO₂), carbonyl sulfide (COS), and the like. In various embodiments, the deposition gas comprises SO₂ or COS, i.e., either exclusively SO₂ or COS or both SO₂ and COS. Additional gases that may be included in the deposition gas are H₂, O₂, and a diluent inert gas (e.g., argon, helium or nitrogen). The plasma process parameters include a chamber pressure of about 30 mTorr to about 300 mTorr, an RF source power of about 50 W to about 800 W at a frequency of about 25 MHz to about 60 MHz, and a pulsed RF bias power of about 0 W (no RF bias) to about 100 W at a frequency of about 0.1 kHz to about 100 kHz. The substrate temperature is controlled from about 0° C. to about 60° C. In this embodiment, the formed etch protection layer 340 (shown in FIG. 3D) can be sulfides or groups with highly oxidized sulfur, such as sulfonic acid groups and sulfates, which result from the deposition of chemical species produced from SO₂/O₂ or SO₂/H₂ plasma dissociation.

In various embodiments, the deposited thickness of the etch protection layer 340 may be between the thickness of about one monolayer of the material to about a few monolayers. In other words, the thickness range may from about 0.3 nm to about 2 nm.

During the etch step (FIG. 3A-box 310 and FIG. 3F), the substrate is exposed to a plasma-excited etching gas. Generally, a lean halogen chemistry, either a chlorine or a fluorine based chemistry, is used for selectively removing metallic molybdenum to extend the recessed features vertically. For example, the recessed feature 336 is further extended to form a recessed feature 342, as illustrated in FIG. 3F. Non-limiting examples of gases comprising fluorine that may be an etching gas include F₂, CF₄, NF₃ and SF₆. Non-limiting examples of gases comprising chlorine that may be an etching gas include Cl₂, CCl₄, and BCl₃. In some embodiments, the gaseous mixture may also include oxygen. In some embodiments, the gaseous mixture may further include an inert gas such as argon. The metallic molybdenum is removed anisotropically, with the removal occurring preferentially from over horizontal surfaces. The anisotropy is achieved by a vertical bias signal applied to the substrate and by depositing the passivating etch protection layer on the vertical sidewalls. As explained above, the bias accelerates ions (e.g., argon ions) vertically and collide with molybdenum atoms. The collisions enhance the etch rate at the bottom surface of the recessed features, e.g., the recessed feature 342. The RF bias signal may be DC or RF or a pulsed RF signal. In some embodiments, a pulsed RF bias power of about 300 W to about 1200 W at a frequency of about 0.1 kHz to about 100 kHz may be used. Other plasma process parameters include a chamber pressure of about 5 mTorr to about 100 mTorr and an RF source power of about 100 W to about 800 W at a frequency of about 25 MHz to about 60 MHz. The substrate temperature is controlled from about 0° C. to about 60° C.

The initial etch step (box 304 and FIG. 3C) may be executed using a process similar to that for the etch step (box 310) used during the gas pulsing cycles 312. The initial etch step is a non-depositing step using, for example, plasma-excited etching gases free of carbon, such as Cl₂.

As illustrated in the cross-sectional view in FIG. 3D, the floor of the extended recessed feature 336 is covered by the solid byproducts deposited to form the etch protection layer 340. In the example embodiment of the gas pulsing cyclic etch technique 300 described with reference to FIGS. 3A-3F, the optional breakthrough etch step (box 308 and FIG. 3E) has been inserted between the deposition step in box 306 and the etch step in box 310 (see the flowchart in FIG. 3A) to expose the molybdenum surface vertically below the recessed feature 336.

In FIG. 3E, the optional breakthrough etch step (box 308) has been performed and a portion of the surface of the metallic molybdenum layer 326 is again exposed to the ambient. In this example embodiment, the breakthrough etch in box 308 is a sputter etch process using, for example, energetic argon ions. Generally, the ions are accelerated by a vertical electric field in the plasma sheath, which may be enhanced by applying a bias signal, such as a pulsed RF bias signal. In some embodiment, a pulsed RF bias power of about 50 W to about 1200 W at a frequency of about 0.1 kHz to about 100 kHz may be applied to the substrate.

While the example embodiment uses the optional breakthrough etch step (box 308) to remove the portion of the etch protection layer 340 formed over the horizontal surface at the bottom of the recessed feature 336, in some other embodiment, the plasma parameters of the etch step in box 310 of each gas pulsing cycle 312 may be adjusted to break through the etch protection layer 340. For example, the oxygen content along with the RF bias power may be increased to help remove the etch protection layer 340 from horizontal surfaces. It is noted that some of the organic polymers in the etch protection layer 340 may be oxidized by the oxygen radicals. Thus, care has to be taken to prevent the oxygen from ashing away the etch protection layer 340 from portions of the surface along the sidewall, resulting in loss of control over the sidewall profile. Once the etch protection layer 340 covering the bottom of the recessed feature 336 is removed, the etch step in box 310 may proceed to extend the recessed feature 336 further down to form the recessed feature 342 in FIG. 3F.

In the above description of the gas pulsing cyclic etch technique 300, the various steps in each gas pulsing cycle 312, i.e., the deposition step in box 306 and the etch step in box 310 are temporally distinct. Temporally separating the two steps not only provides the advantage of independently optimizing the process parameters for the passivation part and the material removal part of the process but also provides and advantage of having a new etch protection layer that passivates a newly formed sidewall portion of the etched metallic molybdenum layer, thereby providing an improved vertical etch profile during each cycle.

In some embodiments, the number of gas pulsing cycles 312 may be a predetermined fixed number in the process recipe. In some other embodiments, the processing may be terminated by a process controller after an endpoint signal is received indicating that the underlying layer 324 has been exposed. In some embodiments an overetch step may be performed after the gas pulsing cyclic etch technique 300 has been executed.

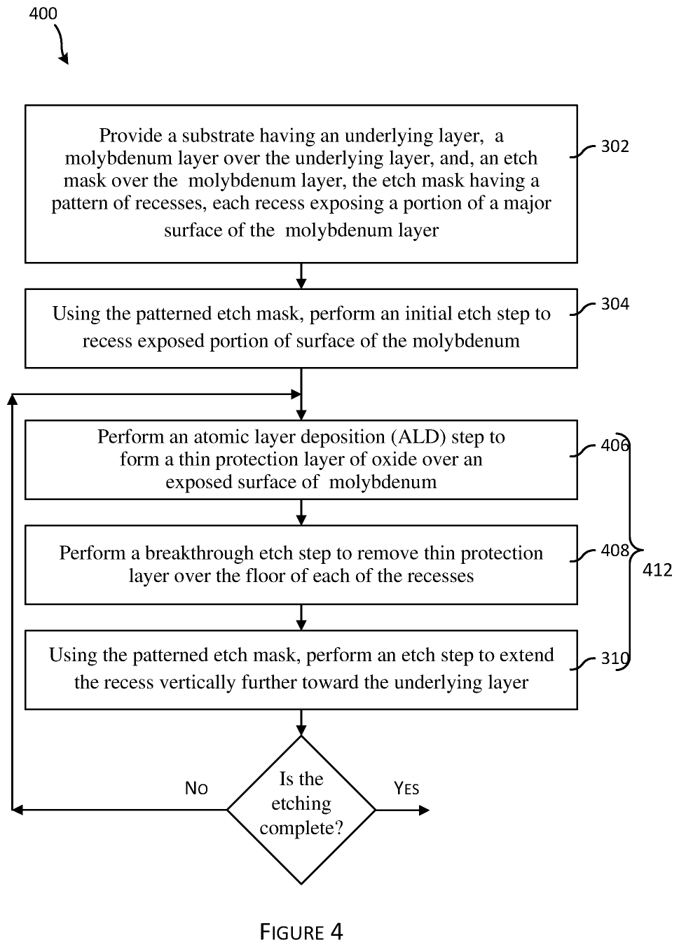

In another embodiment implementing the process flow 100, a deposition-etch cyclic etch technique uses an atomic layer deposition (ALD) process to form an etch protection layer. The ALD-based cyclic etch technique 400 is summarized in a flowchart illustrated in FIG. 4. The ALD-based cyclic etch technique 400 is similar to the gas pulsing cyclic etch technique 300, differing in the method for forming the etch protection layer. Additionally, the optional breakthrough etch step is not optional in the ALD-based cyclic etch technique 400. These changes are indicated by bold lettering in the flowchart in FIG. 4.

The etch protection layer is formed using the ALD technique in the deposition step (box 406) in each deposition-etch cycle 412 of the ALD-based cyclic etch technique 400. The etch protection layer is a thin oxide layer comprising an oxide that has high etch resistance to plasma containing halogen radicals (e.g., chlorine and fluorine radicals). In one example, the oxide layer comprises silicon oxide (SiO₂). As known to persons skilled in the art, in the ALD technique, a deposition reaction is performed as two self-limiting half reactions. In one example, a silicon oxide layer may be deposited by exposing the substrate to a silicon precursor (e.g., SiCl₄ or SiF₄) with or without plasma excitation, followed by an exposure to an oxidant (e.g., plasma-excited oxygen gas).

The etch protection layer may form conformally over the entire exposed surface of the substrate, including the horizontal surface of the metallic molybdenum layer. Thus, the breakthrough etch step (box 408) may not be an optional step. The other steps in the ALD-based cyclic etch technique 400 have been described above in the context of the gas pulsing cyclic etch technique 300 with reference to FIGS. 3A-3F.

Although the deposition and etch steps in the cyclic etch techniques described above may be performed in separate processing chamber, such a process is time consuming and expensive. In the embodiments in this disclosure, the cyclic etch techniques, i.e., the gas pulsing cyclic etch technique 300 and the ALD-based cyclic etch technique 400 may be performed in a single processing chamber with appropriate chamber conditioning steps incorporated in the process flow.

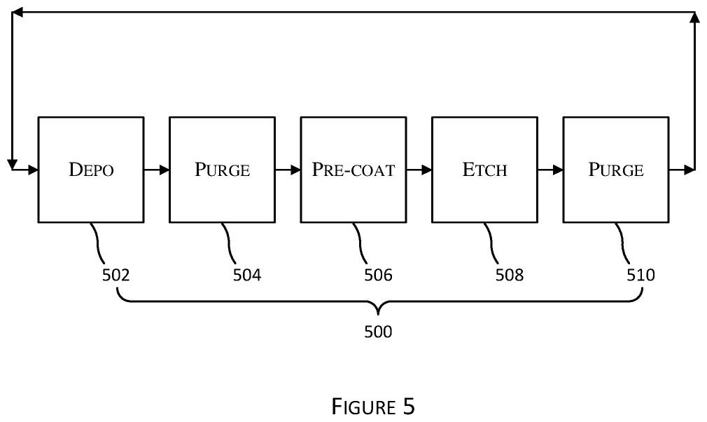

FIG. 5 illustrates a flowchart for one cycle 500 of a cyclic etch process, such as the gas pulsing cycle 312 (of the gas pulsing cyclic etch technique 300) and the deposition-etch cycle 412 (of the ALD-based cyclic etch technique 400). Each cycle 500 has a temporally separated deposition step 502 and an etch step 508. In order to reduce variations in processing, the deposition steps 502 and the etch step 508 include power stabilization and gas flow stabilization periods, as determined by the process controller. Several other actions may be taken to further reduce process induced variations, as illustrated in the flowchart in FIG. 5. A gas purge step 504 may be performed after performing each deposition step 502 to completely remove contaminants and gaseous reaction byproducts. Likewise, another gas purge step 510 may be performed after performing each etch step 508. In some embodiments, a chamber pre-coat step 506 may be performed prior to the etch step 508 to ensure that the initial state of the processing chamber is identical each time the etch step 508 is performed. The chamber pre-coat step deposits a coating on the walls of the processing chamber. The coating may comprise silicon, oxide (e.g., silicon oxide), or carbon, deposited using a plasma process. The chamber pre-coat step 506 is performed with a wafer covering the chuck (substrate holder) to avoid deposition on the chuck. For example, a blank wafer may be placed on the chuck prior to the chamber pre-coat step 506. These additional precautions help meet stringent process control specifications required for integrating metallic molybdenum into high volume IC manufacturing.

As mentioned above, several advantages may be gained by using the described embodiments of cyclic etch processes for patterning metallic molybdenum by separating the passivation part from the material removal part. The advantages include, reduced undercut, low LER, vertical edge profile, and good control of etch rate and etch selectivity. Nevertheless, it is understood that the methods described in this disclosure allow for a partial temporal overlap between deposition and etching. (In embodiments where the gas pulsing cycle 312 includes the optional breakthrough etch step in box 308, the etching refers to the breakthrough etch step in box 308.)

Example embodiments of the invention are summarized here. Other embodiments can also be understood from the entirety of the specification as well as the claims filed herein.
Example 1. A substrate processing method including: providing a substrate containing an etch mask over a metallic molybdenum layer in a recessed feature; exposing the substrate to a plasma-excited deposition gas that forms an etch protection layer on a sidewall of the recessed feature; and exposing the substrate to a plasma-excited etching gas that etches the metallic molybdenum layer according to the etch mask, where the exposing steps are alternatingly performed a plurality of times.
Example 2. The method of example 1, where the plasma-excited deposition gas includes a fluorocarbon (CₓF_{y}), or a hydrofluorocarbon (CₓH_{y}F_{z}), where a ratio of carbon to fluorine atoms greater than 1/4 and less than or equal to 1.
Example 3. The method of one of examples 1 or 2, where the plasma-excited deposition gas includes a sulfur-containing gas.
Example 4. The method of one of examples 1 to 3, where the sulfur-containing gas includes SO₂ or COS gas.
Example 5. The method of one of examples 1 to 4, where the plasma-excited etching gas includes a halogen-containing gas.
Example 6. The method of one of examples 1 to 5, where the halogen-containing gas includes F₂, CF₄, NF₃, SF₆, Cl₂, CCl₄, or BCl₃ gas.
Example 7. The method of one of examples 1 to 6, where the plasma-excited etching gas further includes an oxygen-containing gas.
Example 8. The method of one of examples 1 to 7, where the plasma-excited etching gas further includes argon gas.
Example 9. The method of one of examples 1 to 8, further including: performing a breakthrough etching step that etches through the etch protection layer at a bottom of the recessed feature.
Example 10. The method of one of examples 1 to 9, where exposing the substrate to the plasma-excited etching gas further includes applying a bias signal to the substrate.
Example 11. A substrate processing method including: providing a substrate containing an etch mask over a metallic molybdenum layer in a recessed feature; depositing an etch protection layer in the recessed feature, where the etch protection layer includes an oxide layer; performing a breakthrough etching step that etches through the etch protection layer at a bottom of the recessed feature; and exposing the substrate to a plasma-excited etching gas that etches the metallic molybdenum layer according to the etch mask.
Example 12. The method of example 11, where depositing the etch protection layer includes exposing the substrate to a silicon-containing precursor and an oxidant to form a silicon oxide layer.
Example 13. The method of one of examples 11 or 12, where depositing the etch protection layer includes alternatingly exposing the substrate to a silicon-containing precursor and an oxidant to form a silicon oxide layer.
Example 14. The method of one of examples 11 to 13, where the plasma-excited etching gas includes a halogen-containing gas.
Example 15. The method of one of examples 11 to 14, where the halogen-containing gas includes F₂, CF₄, NF₃, SF₆, Cl₂, CCl₄, or BCl₃ gas.
Example 16. The method of one of examples 11 to 15, where the plasma-excited etching gas further includes an oxygen-containing gas.
Example 17. A substrate processing method including: providing a substrate containing an etch mask over a metallic molybdenum layer in a recessed feature; depositing an etch protection layer on a sidewall of the etch mask, where the etch protection layer includes an oxide layer; and exposing the substrate to a plasma-excited etching gas that etches the metallic molybdenum layer according to the etch mask, where the depositing and the exposing are alternatingly performed a plurality of times.
Example 18. The method of example 17, where exposing the substrate to the plasma-excited etching gas further includes applying a bias signal to the substrate.
Example 19. The method of one of examples 17 or 18, where depositing the etch protection layer includes exposing the substrate to a silicon-containing precursor and an oxidant to form a silicon oxide layer.
Example 20. The method of one of examples 17 to 19, where depositing the etch protection layer includes alternatingly exposing the substrate to a silicon-containing precursor and an oxidant to form a silicon oxide layer.
Example 21. The method of one of examples 17 to 20, where the plasma-excited etching gas includes a halogen-containing gas.
Example 22. The method of one of examples 17 to 21, where the halogen-containing gas includes F₂, CF₄, NF₃, SF₆, Cl₂, CCl₄, or BCl₃ gas.
Example 23. The method of one of examples 17 to 22, where the plasma-excited etching gas further includes an oxygen-containing gas.
Example 24. The method of one of examples 17 to 23, further including: performing a breakthrough etching step that etches through the etch protection layer at a bottom of the recessed feature.
Example 25. The method of one of examples 17 to 24, where the depositing and the exposing are both performed in a processing chamber, and where the method further includes: after the depositing and before the exposing, performing a chamber pre-coat step, the chamber pre-coat step depositing a coating on the walls of the processing chamber.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A substrate processing method comprising:
providing a substrate containing an etch mask over a metallic molybdenum layer in a recessed feature;
exposing the substrate to a plasma-excited deposition gas that forms an etch protection layer on a sidewall of the recessed feature; and
exposing the substrate to a plasma-excited etching gas that etches the metallic molybdenum layer according to the etch mask, wherein the exposing steps are alternatingly performed a plurality of times.

2. The method of claim 1, wherein the plasma-excited deposition gas comprises a fluorocarbon (CₓF_{y}), or a hydrofluorocarbon (CₓH_{y}F_{z}), wherein a ratio of carbon to fluorine atoms greater than 1/4 and less than or equal to 1.

3. The method of claim 1, wherein the plasma-excited deposition gas includes a sulfur-containing gas.

4. The method of claim 3, wherein the sulfur-containing gas comprises SO₂ or COS gas.

5. The method of claim 1, wherein the plasma-excited etching gas comprises a halogen-containing gas.

6. The method of claim 5, wherein the halogen-containing gas comprises F₂, CF₄, NF₃, SF₆ Cl₂, CCl₄, or BCl₃ gas.

7. The method of claim 5, wherein the plasma-excited etching gas further comprises an oxygen-containing gas.

8. The method of claim 5, wherein the plasma-excited etching gas further comprises argon gas.

9. A substrate processing method comprising:
providing a substrate containing an etch mask over a metallic molybdenum layer in a recessed feature;
depositing an etch protection layer in the recessed feature, wherein the etch protection layer includes an oxide layer;
performing a breakthrough etching step that etches through the etch protection layer at a bottom of the recessed feature; and
exposing the substrate to a plasma-excited etching gas that etches the metallic molybdenum layer according to the etch mask.

10. The method of claim 9, wherein depositing the etch protection layer includes exposing the substrate to a silicon-containing precursor and an oxidant to form a silicon oxide layer.

11. The method of claim 9, wherein depositing the etch protection layer includes alternatingly exposing the substrate to a silicon-containing precursor and an oxidant to form a silicon oxide layer.

12. The method of claim 9, wherein the plasma-excited etching gas comprises a halogen-containing gas.

13. The method of claim 12, wherein the halogen-containing gas comprises F₂, CF₄, NF₃, SF₆ Cl₂, CCl₄, or BCl₃ gas.

14. A substrate processing method comprising:
providing a substrate containing an etch mask over a metallic molybdenum layer in a recessed feature;
depositing an etch protection layer on a sidewall of the etch mask, wherein the etch protection layer includes an oxide layer; and
exposing the substrate to a plasma-excited etching gas that etches the metallic molybdenum layer according to the etch mask, wherein the depositing and the exposing are alternatingly performed a plurality of times.

15. The method of claim 14, wherein exposing the substrate to the plasma-excited etching gas further comprises applying a bias signal to the substrate.

16. The method of claim 14, wherein depositing the etch protection layer includes exposing the substrate to a silicon-containing precursor and an oxidant to form a silicon oxide layer.

17. The method of claim 14, wherein depositing the etch protection layer includes alternatingly exposing the substrate to a silicon-containing precursor and an oxidant to form a silicon oxide layer.

18. The method of claim 14, wherein the plasma-excited etching gas comprises a halogen-containing gas.

19. The method of claim 14, further comprising:
performing a breakthrough etching step that etches through the etch protection layer at a bottom of the recessed feature.

20. The method of claim 14,
wherein the depositing and the exposing are both performed in a processing chamber, and
wherein the method further comprises:
after the depositing and before the exposing, performing a chamber pre-coat step, the chamber pre-coat step depositing a coating on the walls of the processing chamber.
